(19) United States
(12) Patent Application Publication
(10) Pub. No.: US 2023/0208381 A1
(43) Pub. Date: Jun. 29, 2023

(54) BULK ACOUSTIC RESONATOR

(71) Applicant: SAMSUNG ELECTRO-MECHANICS CO., LTD., Suwon-si (KR)

(72) Inventors: Moon Chul LEE, Suwon-si (KR); Kwang Su KIM, Suwon-si (KR); Jin Woo YI, Suwon-si (KR); Jae Hyoung GIL, Suwon-si (KR); Yong Suk KIM, Suwon-si (KR); Dong Hyun PARK, Suwon-si (KR)

(73) Assignee: SAMSUNG ELECTRO-MECHANICS CO., LTD., Suwon-si (KR)

(21) Appl. No.: 17/994,706

(22) Filed: Nov. 28, 2022

(30) Foreign Application Priority Data
Dec. 28, 2021 (KR) 10-2021-0189747

(51) Int. Cl. H03H 9/02; H03H 9/13; H03H 9/54

(52) U.S. Cl. CPC H03H 9/02015; H03H 9/132; H03H 9/131; H03H 9/54

(57) ABSTRACT

A bulk acoustic resonator includes a substrate, a frequency control layer changing a resonant frequency or antiresonant frequency of the bulk acoustic resonator according to a thickness of the frequency control layer, a piezoelectric layer disposed between the frequency control layer and the substrate, a first electrode disposed between the piezoelectric layer and the substrate, a second electrode disposed between the piezoelectric layer and the frequency control layer, a metal layer connected to the first electrode or the second electrode, and a protective layer disposed between the second electrode and the frequency control layer, wherein the frequency control layer covers a larger area than that of the protective layer.

### CROSS-REFERENCE TO RELATED APPLICATIONS

This application claims the benefit under 35 USC 119(a) of Korean Patent Application No. 10-2021-0189747 filed on Dec. 28, 2021, in the Korean Intellectual Property Office, the entire disclosure of which is incorporated herein by reference for all purposes.

### BACKGROUND

### 1. Field

The present disclosure relates to a bulk acoustic resonator.

### 2. Description of the Background

Small and lightweight filters, oscillators, resonant elements, acoustic resonant mass sensors, and the like, may be used in mobile communications devices, chemical and biological testing devices, and the like.

An acoustic resonator such as a bulk acoustic wave (BAW) filter may be configured as units implementing such small and lightweight filters, oscillators, resonator elements, and acoustic resonant mass sensors, and have very small and high performance, compared to dielectric filters, metal cavity filters, wave guides, and the like, so that bulk acoustic resonators may be used in communications modules of modern mobile devices that require high performance (e.g., a wide pass bandwidth).

Interest may be directed to technology in communications having a higher frequency or wider bandwidth, such as sub 6 GHz (4 to 6 GHz) of 5G communications and development of a bulk acoustic resonator technology that may be implemented in a candidate band.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic resonator includes a substrate, a frequency control layer changing a resonant frequency or antiresonant frequency of the bulk acoustic resonator according to a thickness of the frequency control layer, a piezoelectric layer disposed between the frequency control layer and the substrate, a first electrode disposed between the piezoelectric layer and the substrate, a second electrode disposed between the piezoelectric layer and the frequency control layer, a metal layer connected to the first electrode or the second electrode, and a protective layer disposed between the second electrode and the frequency control layer, wherein the frequency control layer covers a larger area than that of the protective layer.

The frequency control layer may cover at least a portion of a surface of the protective layer facing the frequency control layer and a surface of the metal layer facing the frequency control layer.

At least a portion of the metal layer may be disposed between a portion of the frequency control layer and a portion of the protective layer.

The frequency control layer may further cover a side surface of the metal layer, and a thickness of a portion of the frequency control layer covering the side surface of the metal layer may be thinner than a thickness of a portion of the frequency control layer covering the second electrode.

A thickness of the protective layer may be 30 nm or more, and may be thinner than a thickness of a portion of the frequency control layer covering the protective layer.

The thickness of the portion of the frequency control layer covering the protective layer may be 60 nm or more.

A thickness of a portion of the frequency control layer covering the protective layer may be 60 nm or more and may be thinner than a thickness of the protective layer.

A frequency sensitivity, which is a rate of change of the resonant frequency or antiresonant frequency of the bulk acoustic resonator according to a change in a thickness of the frequency control layer, may be different from a frequency sensitivity of the protective layer.

Each of the protective layer and the frequency control layer may include one or more of SiO₂, Si₃N₄, Al₂O₃ and AlN, or may include the same material as a piezoelectric material included in the piezoelectric layer.

One of the protective layer and the frequency control layer may include SiO₂, the other of the protective layer and the frequency control layer may include one or more of Si₃N₄, Al₂O₃ and AlN, or may include the same material as the piezoelectric material included in the piezoelectric layer.

A thickness of the layer including SiO₂ among the protective layer and the frequency control layer may be greater.

The protective layer may have stronger chemical resistance than that of the frequency control layer.

The metal layer may be thicker than each of the first and second electrodes, and the metal layer may include a material different from a material included in each of the first and second electrodes.

The bulk acoustic resonator may further include an insertion layer partially disposed between the first and second electrodes, wherein at least one of the protective layer and the frequency control layer includes a portion raised by the insertion layer.

A filter may include a plurality of bulk acoustic resonators, wherein two or more of the plurality of bulk acoustic resonators may include the bulk acoustic resonator, and wherein thicknesses of the frequency control layers of at least two of the two or more of the plurality of bulk acoustic resonators may be different from each other.

In another general aspect, a bulk acoustic resonator includes a substrate, a frequency control layer covering toward the substrate and changing a resonant frequency or antiresonant frequency of the bulk acoustic resonator according to a thickness of the frequency control layer, a metal layer having at least a portion covered by the frequency control layer and connected to a first electrode or a second electrode, a resonant unit including the second electrode, the first electrode disposed between the second electrode and the substrate, and a piezoelectric layer disposed between the first and second electrodes, and a protective layer having at least a portion disposed between the metal layer and the second electrode and between the substrate and the frequency control layer.

At least a portion of the metal layer may be disposed between at least a portion of the frequency control layer and at least a portion of the protective layer.

The frequency control layer may cover a side surface of the metal layer, and a thickness of a portion of the frequency control layer covering the side surface of the metal layer may be thinner than a thickness of a portion of the frequency control layer covering the protective layer.

A thickness of the protective layer may be 30 nm or more, and may be thinner than a thickness of the portion of the frequency control layer covering the protective layer, and a thickness of the portion of the frequency control layer covering the protective layer may be 60 nm or more.

Each of the protective layer and the frequency control layer may include one or more of SiO₂, Si₃N₄, Al₂O₃ and AlN, or may include the same material as a piezoelectric material included in the piezoelectric layer.

The protective layer and the frequency control layer may include different materials.

The metal layer may be thicker than each of the first and second electrodes, and the metal layer may include a material different from a material included in each of the first and second electrodes.

The bulk acoustic resonator may further include an insertion layer partially disposed in the resonant unit, wherein one or more of the protective layer and the frequency control layer may include a portion raised by the insertion layer.

In another general aspect, a bulk acoustic resonator includes a substrate, a frequency control layer changing a resonant frequency or antiresonant frequency of the bulk acoustic resonator according to a thickness, a piezoelectric layer disposed between the frequency control layer and the substrate, a first electrode disposed between the piezoelectric layer and the substrate, a second electrode disposed between the piezoelectric layer and the frequency control layer, a metal layer connected to the first electrode or the second electrode, and a protective layer disposed between the second electrode and the frequency control layer, wherein one of the frequency control layer and the protective layer has a positive temperature coefficient of frequency (TCF) and the other thereof has a negative TCF.

One of the protective layer and the frequency control layer may include SiO₂, and the other of the protective layer and the frequency control layer may include one or more of Si₃N₄, Al₂O₃ and AlN or may include the same material as the piezoelectric material included in the piezoelectric layer.

The frequency control layer may cover at least a portion of a surface of the protective layer facing the frequency control layer and a surface of the metal layer facing the frequency control layer.

At least a portion of the protective layer may be between the metal layer and the second electrode and between the substrate and the frequency control layer.

In another general aspect, a bulk acoustic resonator includes a substrate, a first electrode, a piezoelectric layer, and a second electrode stacked, a metal layer connected to the first electrode, a protective layer disposed between the second electrode and the metal layer to increase galvanic corrosion resistance, and a frequency control layer disposed on the protective layer and comprising a predetermined thickness to control a resonant frequency or antiresonant frequency of the bulk acoustic resonator.

The frequency control layer may be disposed on the metal layer.

A portion of the metal layer may be disposed between the frequency control layer and the protective layer.

A filter may include two or more of the bulk acoustic resonators, wherein the predetermined thicknesses of the frequency control layers of at least two of the two or more bulk acoustic resonators may be different from each other.

At least one of the at least two of the two or more bulk acoustic resonators may be a series bulk acoustic resonator.

At least one of the at least two of the two or more bulk acoustic resonators may be a shunt bulk acoustic resonator connected between the series bulk acoustic resonator and a ground.

Other features and aspects will be apparent from the following detailed description, the drawings, and the claims.

### BRIEF DESCRIPTION OF DRAWINGS

FIG. 1 is a plan view of a bulk acoustic resonator according to an example embodiment in the present disclosure.

FIG. 2 is a cross-sectional view taken along line I-I′ of FIG. 1.

FIG. 3 is a cross-sectional view taken along II-II′ of FIG. 1.

FIG. 4 is a cross-sectional view taken along III-III′ of FIG. 1.

FIGS. 5A, 5B, 5C, and 5D are diagrams illustrating a manufacturing process of a bulk acoustic resonator according to an example embodiment in the present disclosure.

FIG. 6 is a cross-sectional view illustrating thicknesses of a protective layer and a frequency control layer included in a bulk acoustic resonator according to an example embodiment in the present disclosure.

FIG. 7 is a cross-sectional view illustrating effects of a protective layer and a frequency control layer included in a bulk acoustic resonator according to an example embodiment in the present disclosure.

FIG. 8A is a graph illustrating a thickness deviation of a frequency control layer of a bulk acoustic resonator according to an example embodiment in the present disclosure.

FIGS. 8B, 8C, 8D, and 8E are graphs illustrating notch removal near a resonant frequency as a thickness deviation of a frequency control layer of a bulk acoustic resonator decreases according to an example embodiment in the present disclosure.

FIG. 9A is a cross-sectional view illustrating a relationship between modifiable thicknesses of a protective layer and a frequency control layer of a bulk acoustic resonator according to an example embodiment in the present disclosure.

FIG. 9B is a diagram illustrating various material relationships and various thickness relationships of a protective layer and a frequency control layer of a bulk acoustic resonator according to an example embodiment in the present disclosure.

FIG. 10 is a cross-sectional view illustrating a structure in which a hydrophobic layer is further disposed in a bulk acoustic resonator according to an example embodiment in the present disclosure.

FIGS. 11A and 11B are cross-sectional views illustrating a modifiable cover range of a frequency control layer of a bulk acoustic resonator according to an example embodiment in the present disclosure.

FIGS. 12A, 12B, and 12C are cross-sectional views illustrating a modifiable cover range of a protective layer of a bulk acoustic resonator according to an example embodiment in the present disclosure.

FIGS. 13A, 13B, 13C, 13D, 13E, and 13F are cross-sectional views illustrating a modified structure of a resonant unit of a bulk acoustic resonator according to an example embodiment in the present disclosure.

FIGS. 14A and 14B are cross-sectional views illustrating a modified structure of a metal layer of a bulk acoustic resonator according to an example embodiment in the present disclosure. and

FIG. 15 is a perspective view illustrating a filter including a bulk acoustic resonator according to an example embodiment in the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

An aspect of the present disclosure may provide a bulk acoustic resonator.

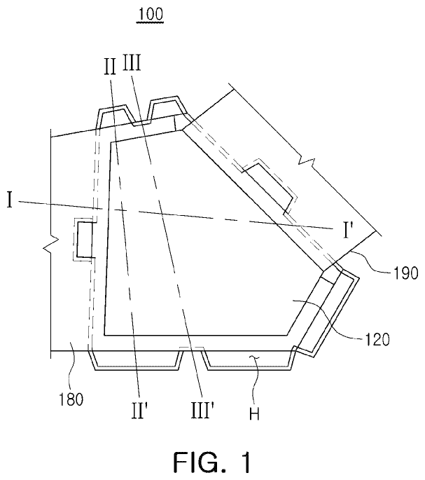

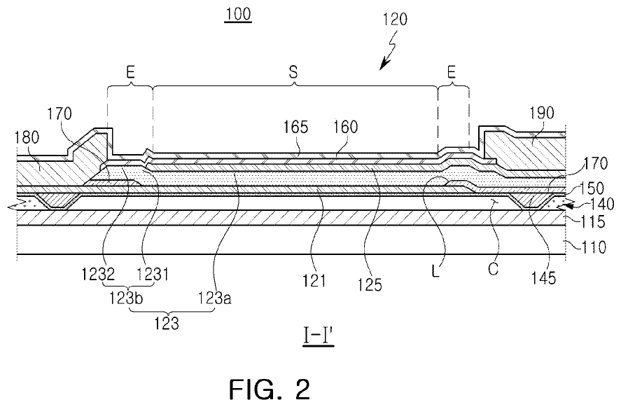

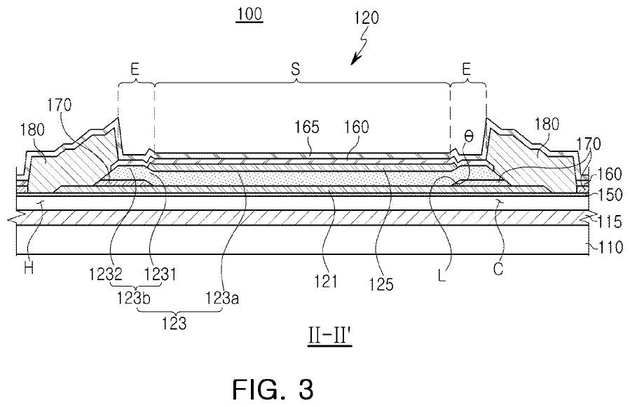

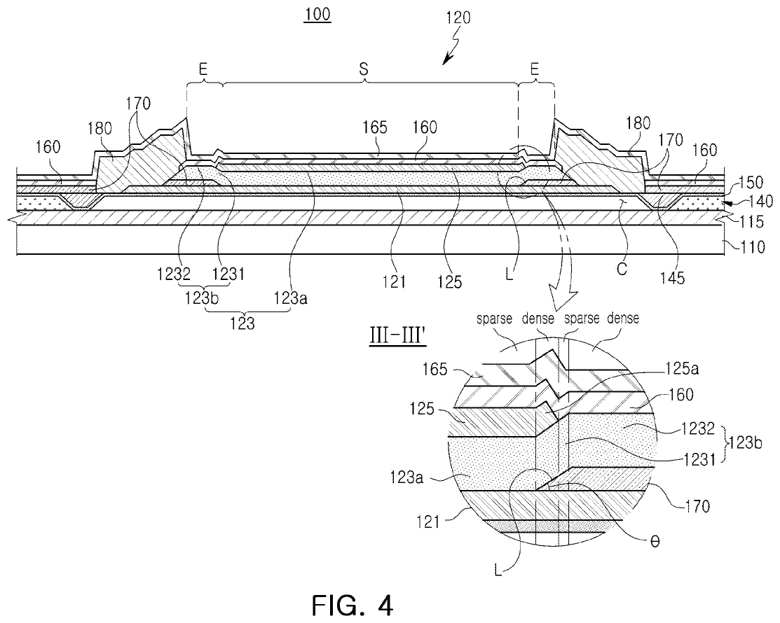

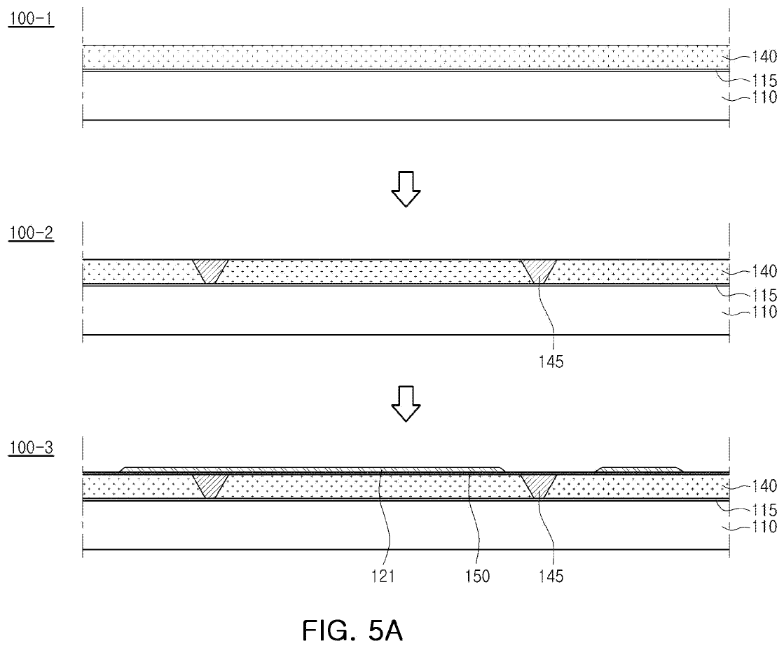

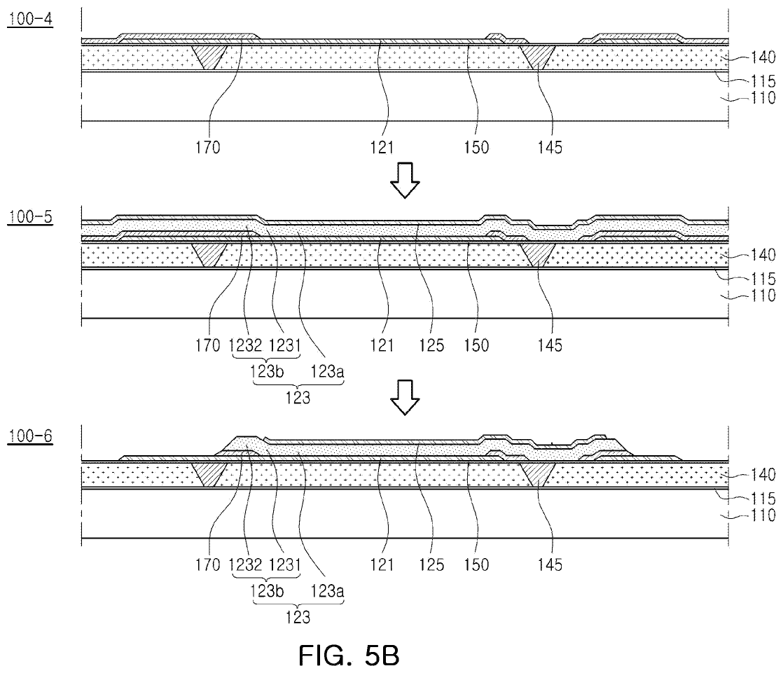

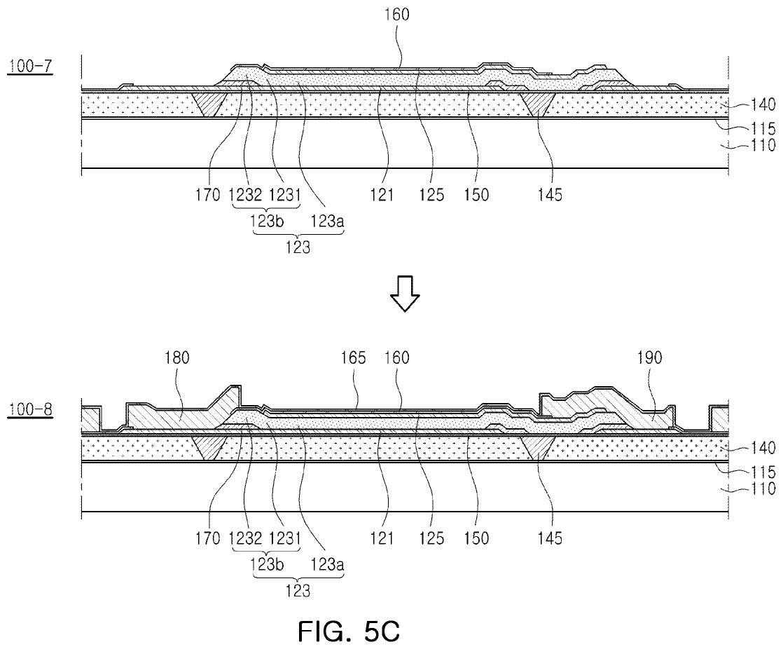

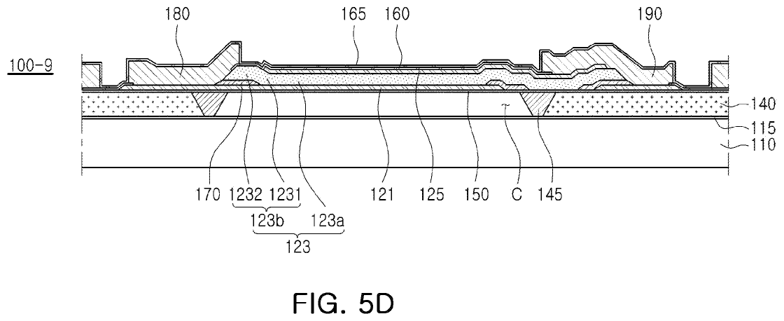

FIG. 1 is a plan view of a bulk acoustic resonator according to an example embodiment in the present disclosure, FIG. 2 is a cross-sectional view taken along line I-I′ of FIG. 1, FIG. 3 is a cross-sectional view taken along II-II′ of FIG. 1, FIG. 4 is a cross-sectional view taken along III-III′ of FIG. 1, and FIGS. 5A to 5D are diagrams illustrating a manufacturing process of a bulk acoustic resonator according to an example embodiment in the present disclosure.

Referring to FIGS. 1 to 4, a bulk acoustic resonator 100 according to an example embodiment in the present disclosure may include a substrate 110, a resonant unit 120, a protective layer 160, a frequency control layer 165, and first and second metal layers 180 and 190.

The substrate 110 may be a silicon substrate. For example, a silicon wafer or a silicon on insulator (SOI) type substrate may be used as the substrate 110.

An insulating layer 115 may be provided on an upper surface of the substrate 110 to electrically isolate the substrate 110 from the resonant unit 120. In addition, the insulating layer 115 may prevent the substrate 110 from being etched by an etching gas when a cavity C is formed during a manufacturing process of the bulk acoustic resonator.

In this case, the insulating layer 115 may be formed of one or more of silicon dioxide (SiO₂), silicon nitride (Si₃N₄), aluminum oxide (Al₂O₃), and aluminum nitride (AlN), may be formed through any one process among chemical vapor deposition, RF magnetron sputtering, and evaporation.

For example, referring to FIG. 5A, a bulk acoustic resonator 100-1 to which a first manufacturing operation is applied may have a structure in which a substrate 110, an insulating layer 115, and a sacrificial layer 140 are sequentially stacked, and a bulk acoustic resonator 100-2 to which a second manufacturing operation is applied may have a structure in which an etch-stop portion 145 is formed.

The sacrificial layer 140 may be formed on the insulating layer 115, and a cavity C and the etch-stop portion 145 may be disposed inside the sacrificial layer 140. The cavity C may be formed as an empty space (e.g., an air cavity), and may be formed by removing a portion of the sacrificial layer 140. As the cavity C is formed in the sacrificial layer 140, the resonant unit 120 formed on the sacrificial layer 140 may be formed to be flat as a whole.

The etch-stop portion 145 may be disposed along the boundary of the cavity C. Since the etch-stop portion 145 may be provided to prevent etching from proceeding beyond the cavity region during a cavity C formation process, the etch-stop portion 145 may include the same material as that of the insulating layer 115, but not limited thereto.

A membrane layer 150 may be formed on the sacrificial layer 140 and may form an upper surface of the cavity C. Accordingly, the membrane layer 150 may also be formed of a material that is not easily removed in the process of forming the cavity C.

For example, when a halide-based etching gas, such as fluorine (F) or chlorine (CI), is used to remove a portion (e.g., a cavity region) of the sacrificial layer 140, the membrane layer 150 may be formed of a material with low reactivity with the etching gas. In this case, the membrane layer 150 may include one or more of silicon dioxide (SiO₂) and silicon nitride (Si₃N₄).

In addition, the membrane layer 150 may be formed of a dielectric layer including a material of one or more of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), and zinc oxide (ZnO), or may be formed of a metal layer including a material of one or more of aluminum (Al), nickel (Ni), chromium (Cr), platinum (Pt), gallium (Ga), and hafnium (Hf).

For example, referring to FIG. 5A, the bulk acoustic resonator 100-3 to which a third manufacturing operation is applied may have a structure in which the membrane layer 150 and a first electrode 121 are further sequentially stacked.

The resonant unit 120 may include the first electrode 121, a piezoelectric layer 123, and a second electrode 125. In the resonant unit 120, the first electrode 121, the piezoelectric layer 123, and the second electrode 125 may be sequentially stacked from the bottom. Accordingly, in the resonant unit 120, the piezoelectric layer 123 may be disposed between the first electrode 121 and the second electrode 125.

Since the resonant unit 120 is formed on the membrane layer 150, the membrane layer 150, the first electrode 121, the piezoelectric layer 123, and the second electrode 125 may be sequentially stacked on the substrate 110 to eventually form the resonant unit 120.

The resonant unit 120 may generate resonance based on the piezoelectric layer 123 according to a frequency of a radio frequency (RF) signal applied to the first electrode 121 and the second electrode 125, and, in particular, may allow the RF signal to easily pass through in one of the resonant frequency and antiresonant frequency and reliably block the RF signal in the other thereof.

The resonant unit 120 may include a central portion S in which the first electrode 121, the piezoelectric layer 123, and the second electrode 125 are stacked to be approximately flat and an extension E in which an insertion layer 170 is interposed between the first electrode 121 and the piezoelectric layer 123.

The central portion S is a region disposed in the center of the resonant unit 120, and the extension E is a region disposed along the circumference of the central portion S. Therefore, the extension E is a region extending outwardly from the central portion S, and refers to a region formed to have a continuous ring shape along the circumference of the central portion S. However, if necessary, the extension E may be formed to have a discontinuous ring shape with a discontinuous partial region.

Accordingly, as shown in FIG. 2, in a cross-section of the resonant unit 120 cut to cross the central portion S, the extensions E may be disposed at both ends of the central portion S. In addition, the insertion layer 170 may be disposed on both sides of the extension E disposed at both ends of the central portion S.

For example, referring to FIG. 5B, a bulk acoustic resonator 100-4 to which a fourth manufacturing operation is applied may have a structure in which the insertion layer 170 is formed, a bulk acoustic resonator 100-5 to which a fifth manufacturing operation is applied may have a structure in which the piezoelectric layer 123 and the second electrode 125 are further stacked, a bulk acoustic resonator 100-6 to which a sixth manufacturing operation is applied may have a structure in which a portion of the first electrode 121, a portion of the piezoelectric layer 123, and a portion of the second electrode 125 are removed, and the insertion layer 170 may have an inclined surface L having a thickness increasing away from the central portion S.

In the extension E, the piezoelectric layer 123 and the second electrode 125 may be disposed on the insertion layer 170. Accordingly, the piezoelectric layer 123 and the second electrode 125 located in the extension E may have inclined surfaces along the shape of the insertion layer 170.

Meanwhile, the extension E may be defined to be included in the resonant unit 120, and thus, resonance may be made in the extension E as well. However, the present disclosure is not limited thereto, and, depending on the structure of the extension E, resonance may not occur in the extension E, but resonance may be made only in the central portion S.

The first electrode 121 and the second electrode 125 may be formed of a conductor and may be formed of, for example, gold, molybdenum, ruthenium, iridium, aluminum, platinum, titanium, tungsten, palladium, tantalum, chromium, nickel, or a metal including one or more thereof.

In the resonant unit 120, the first electrode 121 is formed to have a larger area than the second electrode 125, and the first metal layer 180 is formed on the first electrode 121 along an outer portion of the first electrode 121. Accordingly, the first metal layer 180 may be disposed to be spaced apart from the second electrode 125 by a predetermined distance, and may be disposed to surround the resonant unit 120.

Since the first electrode 121 is disposed on the membrane layer 150, the first electrode 121 is formed to be flat as a whole. Meanwhile, since the second electrode 125 is disposed on the piezoelectric layer 123, the second electrode 125 may have a bent portion to correspond to the shape of the piezoelectric layer 123.

The second electrode 125 is entirely disposed in the central portion S, and is partially disposed in the extension E. Accordingly, the second electrode 125 may be divided into a portion disposed on a piezoelectric portion 123a of the piezoelectric layer 123 to be described later and a portion disposed on a bent portion 123b of the piezoelectric layer 123.

More specifically, in the present example embodiment, the second electrode 125 may be disposed to cover the entire piezoelectric portion 123a and a portion of an inclined portion 1231 of the piezoelectric layer 123. Accordingly, the second electrode (125a in FIG. 4) disposed in the extension E may have a smaller area than the inclined surface of the inclined portion 1231, and in the resonant unit 120, the second electrode 125 may be formed to have an area smaller than the piezoelectric layer 123.

Accordingly, as shown in FIG. 2, in the cross-section in which the resonant unit 120 is cut to cross the central portion S, an end of the second electrode 125 may be disposed in the extension E. Also, the end of the second electrode 125 disposed in the extension E may be disposed such that at least a portion thereof overlaps the insertion layer 170. Here, overlapping means that when the second electrode 125 is projected on a plane on which the insertion layer 170 is disposed, the shape of the second electrode 125 projected on the plane overlaps the insertion layer 170.

Each of the first electrode 121 and the second electrode 125 may be used as any one of an input electrode and an output electrode for inputting and outputting an electrical signal, such as a radio frequency (RF) signal. That is, when the first electrode 121 is used as an input electrode, the second electrode 125 is used as an output electrode, and when the first electrode 121 is used as an output electrode, the second electrode 125 may be used as an input electrode.

As shown in FIG. 4, when the end of the second electrode 125 is located on the inclined portion 1231 of the piezoelectric layer 123 to be described later, a local structure of acoustic impedance of the resonant unit 120 is formed as a sparse/dense/sparse/dense structure from the central portion S, and thus, a reflection interface reflecting a lateral wave toward the inside of the resonant unit 120 may be increased. Accordingly, since most of lateral waves cannot escape to the outside of the resonant unit 120 and are reflected into the inside of the resonant unit 120, the performance of the acoustic resonator may be improved.

The piezoelectric layer 123 is a portion in which a piezoelectric effect that converts electrical energy into mechanical energy in the form of acoustic waves takes place, and may be formed on the first electrode 121 and the insertion layer 170 to be described later.

As a material of the piezoelectric layer 123, zinc oxide (ZnO), aluminum nitride (AlN), doped aluminum nitride, lead zirconate titanate, quartz, and the like, may be selectively used. The doped aluminum nitride may further include a rare earth metal, a transition metal, or an alkaline earth metal. The rare earth metal may include one or more of scandium (Sc), erbium (Er), yttrium (Y), and lanthanum (La). The transition metal may include one or more of hafnium (Hf), titanium (Ti), zirconium (Zr), tantalum (Ta), and niobium (Nb). The alkaline earth metal may also include magnesium (Mg). For example, the content of elements doped into aluminum nitride (AlN) of the piezoelectric layer 123 may be in the range of 0.1 to 30 at %. The element doped into aluminum nitride (AlN) may be scandium (Sc). Accordingly, the piezoelectric constant of the piezoelectric layer 123 may be increased, and kt² of the acoustic resonator may be increased.

For example, the piezoelectric layer 123 may include a piezoelectric portion 123a disposed in the central portion S, and a bent portion 123b disposed in the extension E.

The piezoelectric portion 123a is a portion directly stacked on the upper surface of the first electrode 121. Accordingly, the piezoelectric portion 123a may be interposed between the first electrode 121 and the second electrode 125 to form a flat shape together with the first electrode 121 and the second electrode 125.

The bent portion 123b may be defined as a region extending outward from the piezoelectric portion 123a and located within the extension E.

The bent portion 123b may be disposed on the insertion layer 170 to be described later, and may be formed such that an upper surface is raised along the shape of the insertion layer 170. Accordingly, the piezoelectric layer 123 is bent at a boundary between the piezoelectric portion 123a and the bent portion 123b, and the bent portion 123b may be raised to correspond to the thickness and shape of the insertion layer 170.

The bent portion 123b may be divided into an inclined portion 1231 and an extended portion 1232.

The inclined portion 1231 refers to a portion formed to be inclined along an inclined surface L of the insertion layer 170, which will be described later. In addition, the extended portion 1232 refers to a portion extending outwardly from the inclined portion 1231.

The inclined portion 1231 may be formed parallel to the inclined surface L of the insertion layer 170, and an inclination angle of the inclined portion 1231 may be formed to be the same as an inclination angle of the inclined surface L of the insertion layer 170.

The insertion layer 170 may be disposed along a surface formed by the membrane layer 150, the first electrode 121, and the etch-stop portion 145. Accordingly, the insertion layer 170 may be partially disposed in the resonant unit 120, and disposed between the first electrode 121 and the piezoelectric layer 123.

The insertion layer 170 may be disposed around the central portion S to support the bent portion 123b of the piezoelectric layer 123. Accordingly, the bent portion 123b of the piezoelectric layer 123 may be divided into an inclined portion 1231 and an extended portion 1232 according to the shape of the insertion layer 170.

The insertion layer 170 may be disposed in a region except for the central portion S. For example, the insertion layer 170 may be disposed in the entire region except for the central portion S on the substrate 110 or may be disposed in a partial region.

The insertion layer 170 may be formed to have a thickness that increases away from the central portion S. Accordingly, the insertion layer 170 may be formed as an inclined surface L in which a side surface disposed adjacent to the central portion S has a constant inclination angle θ. For example, the inclination angle θ of a side surface of the insertion layer 170 may be formed in the range of 5° or more and 70° or less.

The inclined portion 1231 of the piezoelectric layer 123 may be formed along the inclined surface L of the insertion layer 170 and may be formed at the same inclination angle as that of the inclined surface L of the insertion layer 170. Accordingly, the inclination angle of the inclined portion 1231 may be formed in the range of 5° or more and 70° or less, similarly to the inclined surface L of the insertion layer 170. The inclination angle of the second electrode 125 stacked on the inclined surface L of the insertion layer 170 may also be formed in a range of 5° or more and 70° or less, similarly to the inclined surface L of the insertion layer 170.

The insertion layer 170 may be formed of a dielectric, such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenic (GaAs), hafnium oxide (HfO₂), titanium oxide (TiO₂), or zinc oxide (ZnO), but may be formed of a material different from that of the piezoelectric layer 123.

For example, the insertion layer 170 may include a metal material, may be formed of an aluminum alloy material including scandium (Sc), and may be formed as a SiO₂ thin film implanted with nitrogen (N) or fluorine (F).

The resonant unit 120 may be spaced apart from the substrate 110 through the cavity C formed as an empty space. The cavity C may be formed by removing a portion of the sacrificial layer 140 by supplying an etching gas (or an etching solution) to an inlet hole (H of FIG. 1) during a manufacturing process of the bulk acoustic resonator.

A protective layer 160 may be disposed along the surface of the bulk acoustic resonator 100 to protect the bulk acoustic resonator 100 from the outside. The protective layer 160 may be disposed along a surface formed by the second electrode 125 and the bent portion 123b of the piezoelectric layer 123.

The first electrode 121 and the second electrode 125 may extend outside the resonant unit 120. In addition, a first metal layer 180 and a second metal layer 190 may be disposed on an upper surface of the extended portion.

The first metal layer 180 and the second metal layer 190 may be formed of a material of any one of gold (Au), a gold-tin (Au—Sn) alloy, copper (Cu), a copper-tin (Cu—Sn) alloy, aluminum (Al), and an aluminum alloy. Here, the aluminum alloy may be an aluminum-germanium (Al—Ge) alloy or an aluminum-scandium (Al—Sc) alloy.

The first metal layer 180 and the second metal layer 190 may function as connecting wirings electrically connecting the electrodes 121 and 125 of the acoustic resonator according to the present example embodiment on the substrate 110 and electrodes of another acoustic resonator disposed adjacent thereto.

The first metal layer 180 may be bonded to the first electrode 121 through the protective layer 160.

In addition, in the resonant unit 120, the first electrode 121 may have a larger area than the second electrode 125, and the first metal layer 180 may be formed on a circumferential portion of the first electrode 121.

Accordingly, the first metal layer 180 may be disposed along the circumference of the resonant unit 120 and may be disposed to surround the second electrode 125, but the present disclosure is not limited thereto.

At least a portion of the protective layer 160 positioned on the resonant unit 120 may be disposed to contact the first metal layer 180 and the second metal layer 190. Since the first metal layer 180 and the second metal layer 190 may be formed of a metal material having high thermal conductivity, the first metal layer 180 and the second metal layer 190 have a large volume, and thus a heat dissipation effect may be large.

Therefore, the protective layer 160 may be connected to the first metal layer 180 and the second metal layer 190 so that heat generated in the piezoelectric layer 123 may be quickly transferred to the first metal layer 180 and the second metal layer 190 via the protective layer 160.

For example, at least a portion of the protective layer 160 may be disposed below the first metal layer 180 and the second metal layer 190 and may be inserted to be disposed between the first metal layer 180 and the piezoelectric layer 123 and between the second metal layer 190 and the second electrode 125 and the piezoelectric layer 123.

The frequency control layer 165 may be disposed on an upper side of the substrate 100 to cover the substrate 100.

For example, referring to FIG. 5C, a bulk acoustic resonator 100-7 to which a seventh manufacturing operation is applied may have a structure in which the protective layer 160 is further stacked, and a bulk acoustic resonator 100-8 to which an eighth manufacturing operation is applied may have a structure in which the first and second metal layers 180 and 190 are stacked and the frequency control layer 165 is further stacked. Referring to FIG. 5D, a bulk acoustic resonator 100-9 to which a ninth manufacturing operation is applied may have a structure in which a cavity C is formed.

Since the first to ninth manufacturing operations of FIGS. 5A to 5D may be sequentially applied, the protective layer 160 may be formed earlier than the first and second metal layers 180 and 190, and the frequency control layer 165 may be formed after the first and second metal layers 180 and 190 are formed. Accordingly, the protective layer 160 may prevent galvanic corrosion and increase galvanic isolation (refer to FIG. 7) between the first and second metal layers 180 and 190 and the second electrode 125, and the frequency control layer 165 may improve trim uniformity (refer to FIG. 7).

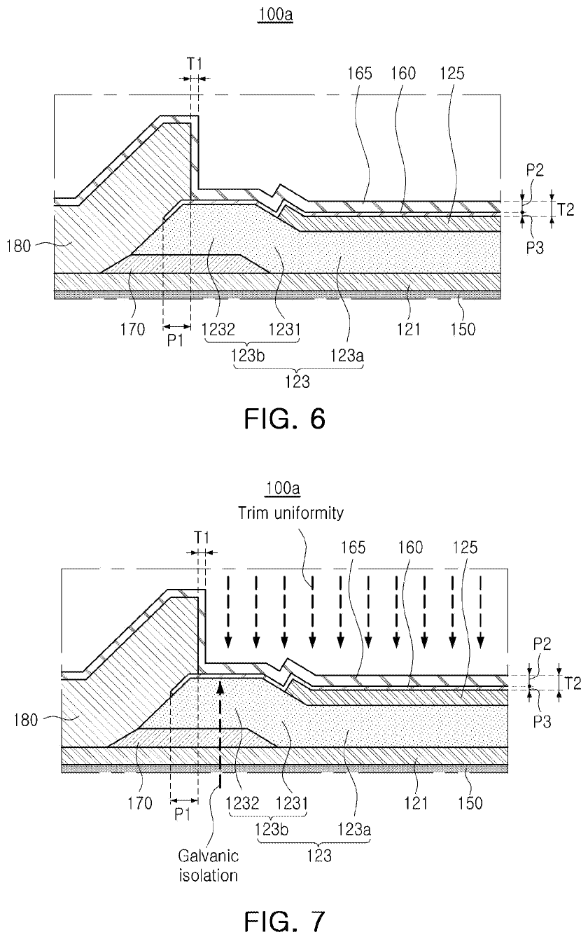

FIG. 6 is a cross-sectional view illustrating thicknesses of a protective layer and a frequency control layer included in a bulk acoustic resonator according to an example embodiment in the present disclosure, and FIG. 7 is a cross-sectional view illustrating effects of the protective layer and a frequency control layer included in the bulk acoustic resonator according to an example embodiment in the present disclosure.

Referring to FIGS. 6 and 7, the frequency control layer 165 may cover a larger area than the protective layer 160. Alternatively, the frequency control layer 165 may cover the first metal layer 180.

For example, the frequency control layer 165 may cover at least portions of a surface (e.g., an upper surface) of the protective layer 160 facing the frequency control layer 165 and a surface (e.g., a side surface and/or an upper surface) of the first metal layer 180 facing the frequency control layer 165 together, thereby covering a larger area than the protective layer 160.

Here, the first metal layer 180 may be the second metal layer 190 illustrated in FIGS. 1 to 4. That is, the first metal layer 180 connected to the first electrode 121 illustrated in FIGS. 6 through 14A may be replaced by the second metal layer 190 connected to the second electrode 125, and the metal layer connected to the first electrode or the second electrode may be the first metal layer 180 or the second metal layer 190.

The resonant frequency and/or antiresonant frequency of the bulk acoustic resonator 100a according to an example embodiment in the present disclosure may be determined based on acoustic impedance of the bulk acoustic resonator 100a, and the acoustic impedance may be a value obtained by dividing a product of acoustic pressure and acoustic speed by a vertical area, and the vertical area may be proportional to an overall thickness of the bulk acoustic resonator 100a.

When a thickness P2 of a portion of the frequency control layer 165 that vertically overlaps the second electrode 125 changes, an overall thickness of the bulk acoustic resonator 100a may also change. When the acoustic pressure of the frequency control layer 165 is different from an overall acoustic pressure other than the frequency control layer 165, an overall acoustic pressure of the bulk acoustic resonator 100a may also change according to the change in the thickness P2 of the frequency control layer 165.

That is, since the thickness P2 of the frequency control layer 165 may affect the overall thickness and/or overall acoustic pressure of the bulk acoustic resonator 100a, the thickness P2 may also affect the acoustic impedance of the bulk acoustic resonator 100a. That is, the resonant frequency and/or antiresonant frequency of the bulk acoustic resonator 100a may change according to the thickness P2 of the frequency control layer 165.

The thickness P2 of the frequency control layer 165 may be determined by adjusting a time for which the frequency control layer 165 is deposited or by adjusting a time for which the frequency control layer 165 is etched after the frequency control layer 165 is formed. For example, the etching of the frequency control layer 165 may be one or more of physical (e.g., dry etching, fine particle collision) etching, chemical (e.g., wet etching, using an etching gas used to form a cavity) etching, and reactive ion etching, but is not limited thereto.

The process of determining the thickness P2 of the frequency control layer 165 so that the resonant frequency and/or antiresonant frequency of the bulk acoustic resonator 100a is close to a target frequency may be defined as trim.

Trim uniformity of the frequency control layer 165 may be defined as an application deviation of means (e.g., etching, deposition) that determines the thickness P2 of the frequency control layer 165 according to a horizontal position of the frequency control layer 165. As the trim uniformity is higher, a rate of change in the thickness of the frequency control layer 165 according to a change in the horizontal position may be reduced, the thickness of the frequency control layer 165 may be more apparent, and the resonant frequency and/or antiresonant frequency of the bulk acoustic resonator 100a may also be apparent. The apparent resonant frequency and/or antiresonant frequency means that there is a little notch in which the impedance locally changes greatly or spurious in which the impedance locally fluctuates near the resonant frequency and/or antiresonant frequency. That is, the notch and/or spurious near the resonant frequency and/or antiresonant frequency of the bulk acoustic resonator 100a may decrease as the trim uniformity of the frequency control layer 165 increases.

Trim uniformity may increase as structural and/or material homogeneity between a portion to which trim is applied (e.g., an upper side of the second electrode 125) and other portions increases. When the frequency control layer 165 covers the trim-applied portion (e.g., the upper side of the second electrode 125) and the other portions together, the structural and/or material homogeneity between the trim-applied portion and the other portions may increase.

Accordingly, trim uniformity may increase as the area covered by the frequency control layer 165 increases. Alternatively, trim uniformity may be increased when the frequency control layer 165 covers the first metal layer 180. Since the frequency control layer 165 may cover a larger area than the protective layer 160, trim uniformity may be increased, and notch and/or spurious near the resonant frequency and/or antiresonant frequency may be reduced.

Referring to FIGS. 6 and 7, the protective layer 160 may be disposed between the second electrode 125 and the frequency control layer 165. Alternatively, at least a portion of the protective layer 160 may be disposed between the first metal layer 180 and the second electrode 125 between the substrate (a lower side of the membrane layer 150) and the frequency control layer 165.

Accordingly, the protective layer 160 may increase galvanic isolation between the first metal layer 180 and the second electrode 125, and therefore, galvanic corrosion between first metal layer 180 and the second electrode 125 may be prevented.

At least a portion of the first metal layer 180 may be disposed between a portion of the frequency control layer 165 and a portion of the protective layer 160. Accordingly, galvanic isolation between the first metal layer 180 and the second electrode 125 may further increase. The protective layer 160 may be formed before the first metal layer 180, and the frequency control layer 165 may be formed later than the first metal layer 180.

For example, the protective layer 160 may penetrate through between a surface of the first metal layer 180 and a surface of the piezoelectric layer 123 so that a portion of the first metal layer 180 forms a step. As a penetration length P1 of the protective layer 160 is longer, galvanic isolation between the first metal layer 180 and the second electrode 125 may be higher.

For example, the first metal layer 180 may be thicker than that of each of the first and second electrodes 121 and 125, and the first metal layer 180 may include a material (e.g., a material having high conductivity such as gold, silver, and copper) different from a material (e.g., a material effective to support piezoelectric properties such as molybdenum) included in each of the first and second electrodes 121 and 125. Accordingly, electrical resistance of the first metal layer 180 may be lowered, and thus, overall input/output energy loss of the bulk acoustic resonator 100a may be reduced. The bulk acoustic resonator 100a according to an example embodiment in the present disclosure may improve trim uniformity, without being substantially affected by the relatively large thickness of the first metal layer 180, and may improve trim uniformity and/or galvanic isolation, without being substantially affected by a material difference between the first metal layer 180 and the second electrode 125.

For example, one or more of the protective layer 160 and the frequency control layer 165 may include a portion raised by the insertion layer 170. Since the raised portion may reduce a lateral acoustic wave of the bulk acoustic resonator 100a or lateral leakage of the lateral acoustic wave, the overall energy loss of the bulk acoustic resonator 100a may be reduced. The bulk acoustic resonator 100a according to an example embodiment in the present disclosure may improve trim uniformity, without being substantially affected by a difference in height of the frequency control layer 165 according to the raised portion.

The frequency control layer 165 may further cover a side surface of the first metal layer 180, and a thickness T1 of a portion of the frequency control layer 165 covering the side surface of the first metal layer 180 may be thinner than a total thickness T2 of the thickness P2 of the portion of the frequency control layer 165 covering the second electrode and a thickness P3 of the protective layer 160. Since the insulating properties of the protective layer 160 may be affected by the insulating properties of the frequency control layer 165, a possibility that a difference in specific acoustic impedance between the protective layer 160 and the frequency control layer 165 is smaller than a difference in specific acoustic impedance between the protective layer 160 or the frequency control layer 165 and the first electrode 121 or the second electrode 125 may be high. Accordingly, the thickness of the protective layer 160 may act close to a portion of the thickness of the frequency control layer 165, and the protective layer 160 may offset a portion of an influence of a change in the thickness of the frequency control layer 165 due to a process distribution on the resonant frequency and/or antiresonant frequency, and the resonant frequency and/or the antiresonant frequency may be implemented more accurately.

Here, a reference direction of the thicknesses T1, T2, P2, and P3 may be defined as a direction perpendicular to a lower surface of the corresponding portion. For example, the thicknesses T1, T2, P2, and P3 may be measured by analysis using one or more of transmission electron microscopy (TEM), atomic force microscope (AFM), scanning electron microscope (SEM), an optical microscope, and a surface profiler.

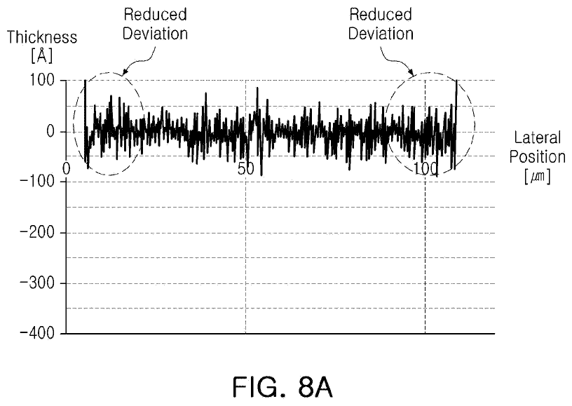

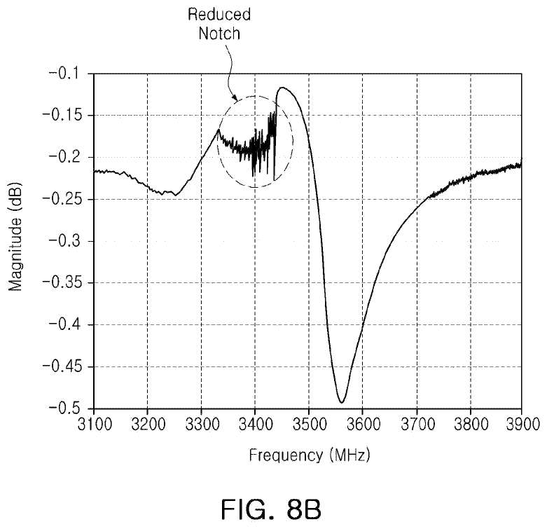

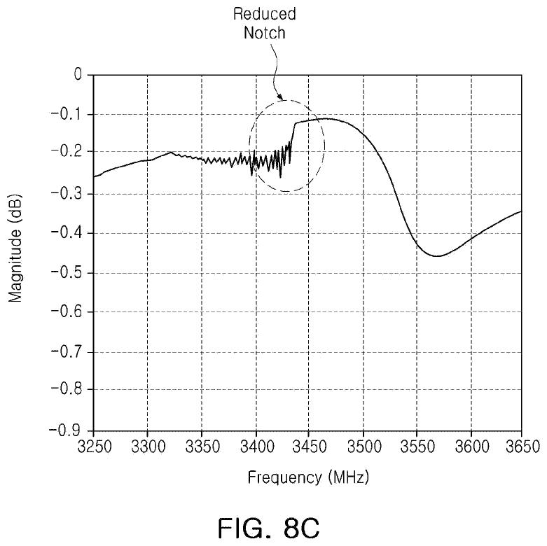

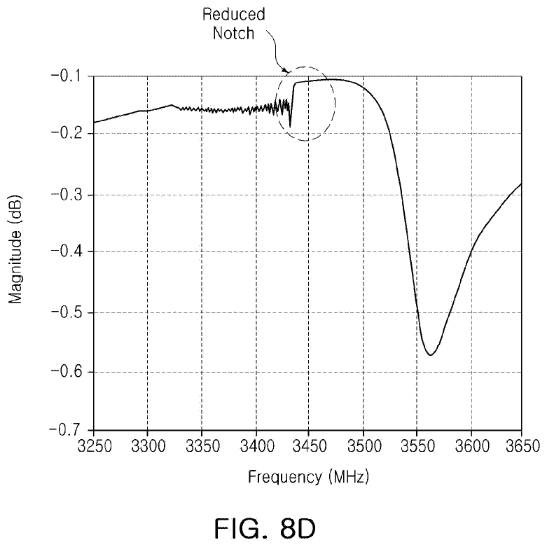

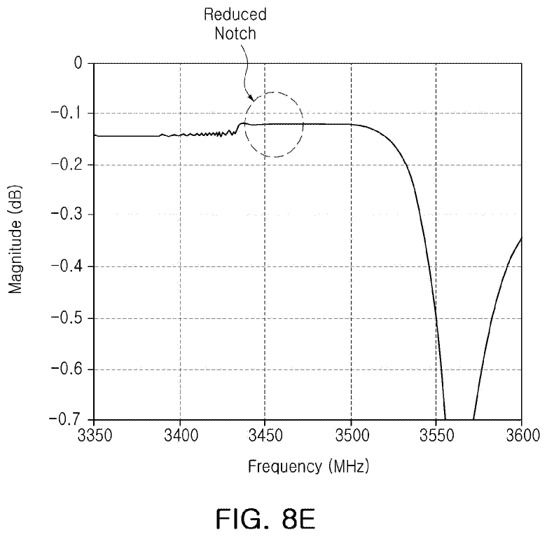

FIG. 8A is a graph illustrating a thickness deviation of a frequency control layer of a bulk acoustic resonator according to an example embodiment in the present disclosure.

Referring to FIG. 8A, a lateral length of the resonant unit of the bulk acoustic resonator (corresponding to the square root of a horizontal area) may be about 100 μm (microns), and a difference between the thickness of the frequency control layer and each of a minimum value and a maximum value of the thickness of the frequency control layer according to a lateral position may be less than 10 nm (nanometers). That is, a thickness deviation of the frequency control layer may be less than 20 nm. When the trim uniformity is low, an absolute value of the minimum value or the maximum value of the thickness of the portion covering the edge of the resonant unit in the frequency control layer may increase, but the frequency control layer of the bulk acoustic resonator according to an example embodiment in the present disclosure may have a thickness with reduced deviation through improved trim uniformity.

FIGS. 8B through 8E are graphs illustrating notch removal near a resonant frequency as a thickness deviation of a frequency control layer of a bulk acoustic resonator decreases according to an example embodiment in the present disclosure.

The curve of FIG. 8B illustrates an S-parameter of the resonant unit when the lateral length of the resonant unit is about 100 μm, and FIGS. 8C through 8E illustrate an S-parameter of the resonant unit when the lateral length of the resonant unit is sequentially further increased. For example, the S-parameter of FIGS. 8B through 8E may be measured by electrically connecting a terminal of a nonlinear vector network analyzer to an electrode or a metal layer.

Referring to FIGS. 8B through 8E, the S-parameter between the first and second metal layers of the bulk acoustic resonator according to a frequency may be increased or decreased according to the resonant frequency and the antiresonant frequency in the vicinity of about 3.5 GHz. Here, 3.5 GHz may vary depending on the design. When trim uniformity is low, the S-parameter may indicate a notch that is locally lowered near the resonant frequency, but the S-parameter of the bulk acoustic resonator according to an example embodiment in the present disclosure may exhibit characteristics that the notch is reduced in the vicinity of the resonant frequency.

For example, the notch may be defined such that a difference between a minimum value (e.g., −0.23 dB in FIG. 8B) and an average value (e.g., −0.18 dB in FIG. 8B) of the S-parameter in a frequency range, from a frequency (e.g., 3.35 GHz in FIG. 8B) obtained by subtracting a difference (e.g., 100 MHz in FIG. 8B) between the resonant frequency and the antiresonant frequency from the resonant frequency, to the resonant frequency (e.g., 3.45 GHz in FIG. 8B) is greater than a reference (e.g., difference of 1 dB), and thus, the corresponding frequency range of the S-parameters of FIGS. 8B to 8E does not include a notch.

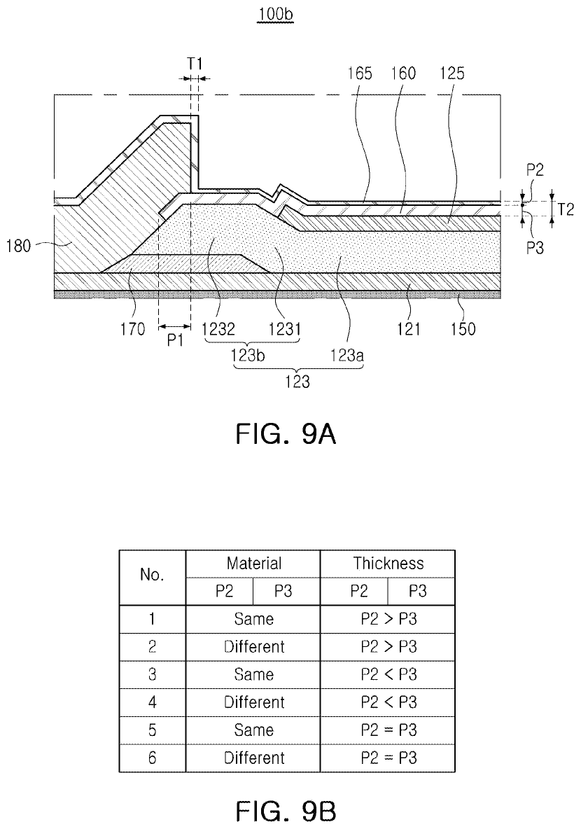

FIG. 9A is a cross-sectional view illustrating a relationship between modifiable thicknesses of a protective layer and a frequency control layer of a bulk acoustic resonator according to an example embodiment in the present disclosure, and FIG. 9B is a diagram illustrating various material relationships and various thickness relationships of a protective layer and a frequency control layer of a bulk acoustic resonator according to an example embodiment in the present disclosure.

Referring to FIG. 9A, the thickness P3 of the protective layer 160 of the bulk acoustic resonator 100b according to an example embodiment in the present disclosure may be thicker than the thickness P2 of the frequency control layer 165.

Referring to FIG. 9B, the number of cases of thickness relationships between the thickness P3 of the protective layer 160 and the thickness P2 of the frequency control layer 165 may be 3, and the number of cases of material relationships of the protective layer 160 and the frequency control layer 165 may be 2. For example, each of the protective layer 160 and the frequency control layer 165 may include one or more of SiO₂, Si₃N₄, Al₂O₃, and AlN, or may include the same material as a piezoelectric material contained in the piezoelectric layer. Accordingly, since each of the protective layer 160 and the frequency control layer 165 may have stronger chemical resistance, the bulk acoustic resonator may be robust to external environmental changes. For example, a redox action of the resonant unit according to a change in the external environment of the second electrode and/or the first and second metal layers may be suppressed.

Since there is also a difference in chemical resistance between candidate materials (e.g., SiO₂, Si₃N₄, Al₂O₃, and AlN) that may be included in the protective layer 160 and the frequency control layer 165, the protective layer 160 may include materials having relatively high chemical resistance among the candidate materials. For example, the chemical resistance of the protective layer 160 may be stronger than the chemical resistance of the frequency control layer 165. Accordingly, the protective layer 160 may more effectively suppress galvanic corrosion between the metal layer and the electrode. For example, chemical resistance may be measured as the amount (or thickness) of redox per unit time when the corresponding layer is exposed to a specific atmosphere.

SiO₂ may have strong chemical resistance and a positive temperature coefficient of frequency (TCF). The TCF may be defined as a change ratio of the resonant frequency or antiresonant frequency according to a temperature change.

The chemical resistance and the TCF may have a correlation. Accordingly, when the protective layer 160 and the frequency control layer 165 have different TCFs, the protective layer 160 may have improved chemical resistance to suppress electro-chemical corrosion between the metal layer and the electrode.

In addition, one of the protective layer 160 and the frequency control layer 165 may have a positive TCF and the other thereof may have a negative TCF. Accordingly, since the overall TCFs of the protective layer 160 and the frequency control layer 165 may be close to zero, the bulk acoustic resonator according to an example embodiment in the present disclosure may be robust to temperature changes, and stability of the resonant frequency or antiresonant frequency may be increased. In addition, electro-chemical corrosion between the metal layer and the electrode may also be suppressed.

For example, one of the protective layer 160 and the frequency control layer 165 may include SiO₂ having a positive TCF, and the other of the protective layer 160 and the frequency control layer 165 may include one or more of Si₃N₄, Al₂O₃, and AlN having a negative TCF or may include the same material as the piezoelectric material (that may have a negative TCF) included in the piezoelectric layer.

Since the piezoelectric material included in the piezoelectric layer may have a negative TCF, a layer including SiO₂ having a positive TCF among the protective layer 160 and the frequency control layer 165 may be thicker. Accordingly, the overall TCF of the bulk acoustic resonator according to an example embodiment in the present disclosure may be closer to zero.

Frequency sensitivity, which is a rate of change of the resonant frequency or antiresonant frequency of the bulk acoustic resonator according to a change in the thickness of the frequency control layer 165, may be different from frequency sensitivity of the protective layer 160. For example, since the frequency sensitivities of SiO₂, Si₃N₄, Al₂O₃, and AlN may be 1 nm/MHz, 1.3 nm/MHz, 0.88 nm/MHz and 0.78 nm/MHz, respectively, the material included in the protective layer 160 may be some of SiO₂, Si₃N₄, Al₂O₃, and AlN, and the material included in the frequency control layer 165 may be others of SiO₂, Si₃N₄, Al₂O₃, and AlN.

For example, when the thickness P2 of the frequency control layer 165 is thicker than the thickness P3 of the protective layer 160, the frequency sensitivity of the frequency control layer 165 may be designed be free relatively. When the thickness P2 of the frequency control layer 165 is thinner than the thickness P3 of the protective layer 160, the frequency sensitivity of the frequency control layer 165 may be designed to be low in order to reduce the influence of a deposition process distribution.

For example, the thickness P2 of the frequency control layer 165 may be 60 nm or more. Accordingly, the change in the resonant frequency or the antiresonant frequency according to the deposition process distribution may be effectively reduced.

For example, the thickness P3 of the protective layer 160 may be 30 nm or more. Accordingly, distribution continuity of the protective layer 160 on the resonant unit may be stably secured, so that the electro-chemical corrosion between the metal layer and the electrode may be stably suppressed.

For example, the thickness P2 of the frequency control layer 165 may be 150 nm, and the thickness P3 of the protective layer 160 may be 30 nm or more and 50 nm or less.

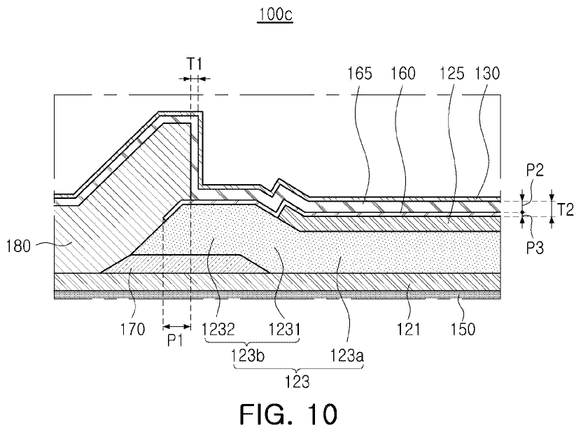

FIG. 10 is a cross-sectional view illustrating a structure in which a hydrophobic layer is further disposed in a bulk acoustic resonator according to an example embodiment in the present disclosure.

Referring to FIG. 10, a bulk acoustic resonator 100c according to an example embodiment in the present disclosure may further include a hydrophobic layer 130 disposed on the frequency control layer 165. Since the hydrophobic layer 130 may suppress adsorption of water and hydroxyl groups (OH groups) on the upper surface of the bulk acoustic resonator 100c, fluctuation of the resonant frequency or antiresonant frequency may be reduced. For example, the frequency control layer 165 may be thicker than the hydrophobic layer 130 and may have higher frequency sensitivity.

For example, the hydrophobic layer 130 may be formed by vapor deposition of a precursor that may have hydrophobicity, and may include a fluorocarbon having a silicon (Si) head or hydrocarbon or siloxane having a silicon (Si) head.

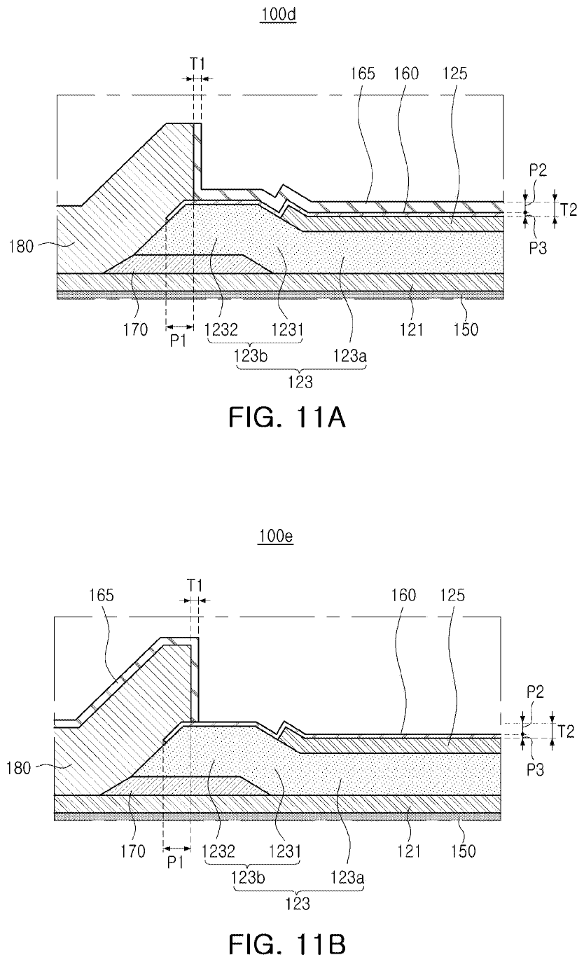

FIGS. 11A and 11B are cross-sectional views illustrating a modifiable cover range of a frequency control layer of a bulk acoustic resonator according to an example embodiment in the present disclosure.

Referring to FIG. 11A, the frequency control layer 165 of a bulk acoustic resonator 100d according to an example embodiment in the present disclosure may not cover the upper surface of the first metal layer 180 according to design. Since the frequency control layer 165 of the bulk acoustic resonator 100d may cover the side surface of the first metal layer 180 and may cover a wider range than the protective layer 160, the frequency control layer 165 may be implemented by improved trim uniformity.

Referring to FIG. 11B, the frequency control layer 165 of a bulk acoustic resonator 100e according to an example embodiment may not cover the second electrode 125 according to design. The frequency control layer 165 of the bulk acoustic resonator 100e may cover the side surface of the first metal layer 180 and homogeneity between the frequency control layer 165 and the protective layer 160 may be higher than homogeneity between the protective layer 160 and the first metal layer 180, and thus, the frequency control layer 165 may be implemented by improved trim uniformity.

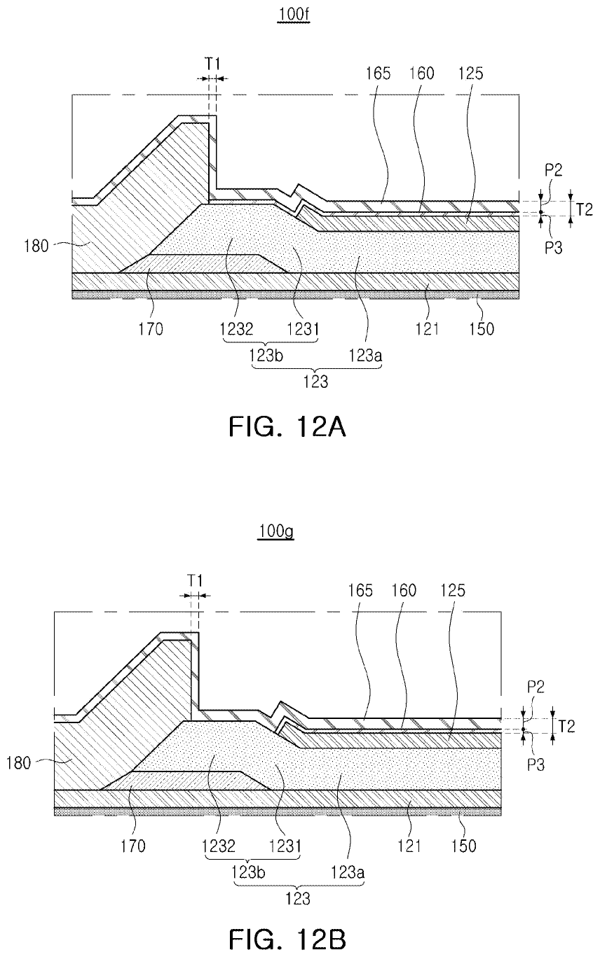

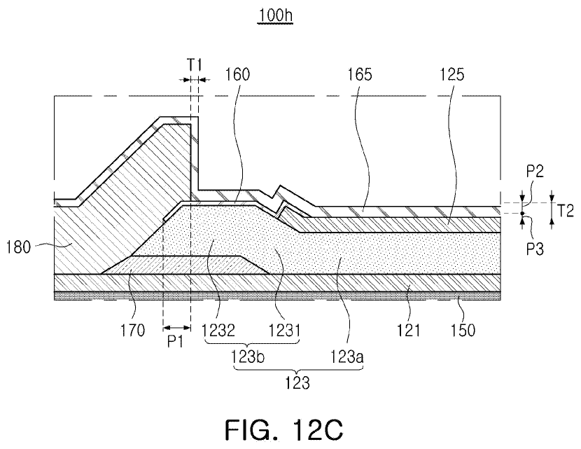

FIGS. 12A through 12C are cross-sectional views illustrating a modifiable cover range of a protective layer of a bulk acoustic resonator according to an example embodiment in the present disclosure.

Referring to FIGS. 12A and 12B, the protective layer 160 of bulk acoustic resonators 100f and 100g according to an example embodiment in the present disclosure may not be disposed on the lower surface of the first metal layer 180 according to design.

Referring to FIG. 12C, the protective layer 160 of a bulk acoustic resonator 100h according to an example embodiment may not cover a portion of the second electrode 125 according to design.

The protective layer 160 of the bulk acoustic resonators 100f, 100g, and 100h may be disposed between the frequency control layer 165 and the second electrode 125 or between the first metal layer 180 and the second electrode 125, galvanic isolation between the first metal layer 180 and the second electrode 125 may be improved.

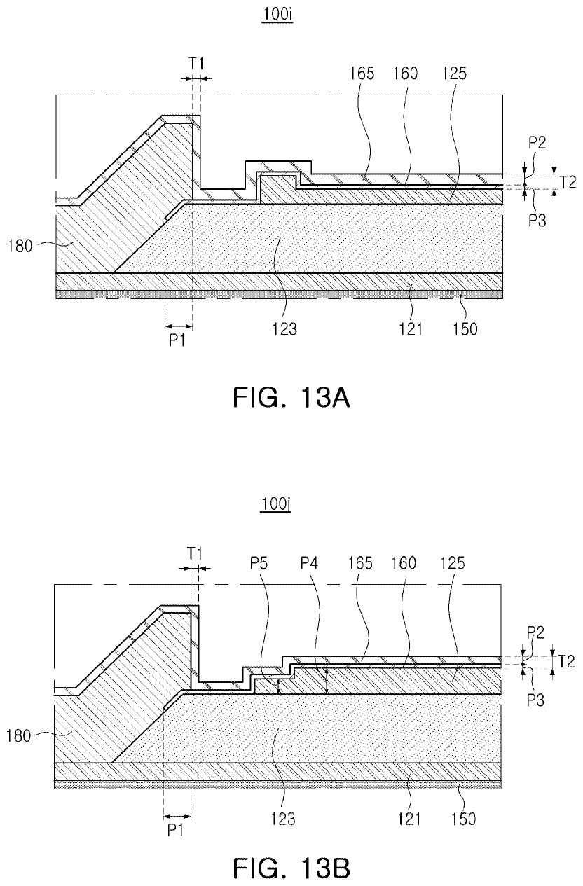

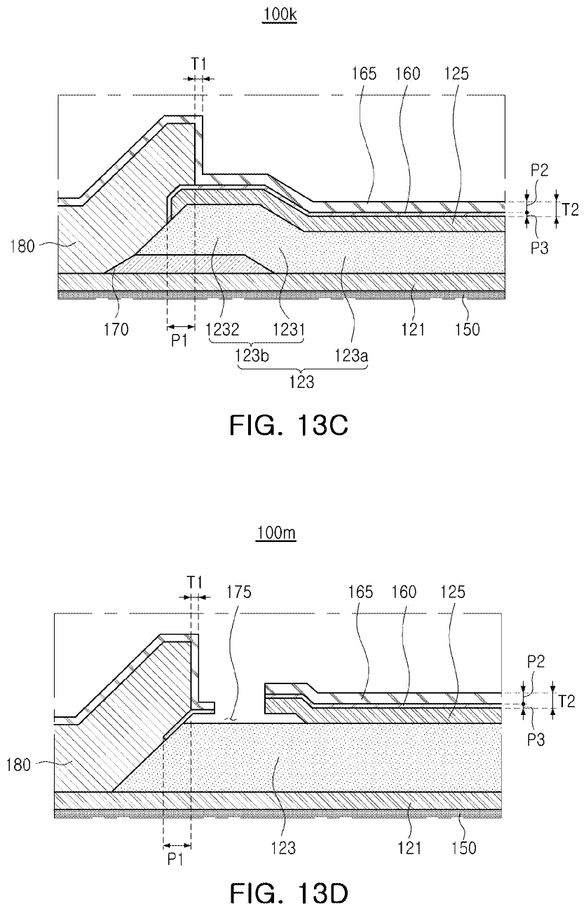

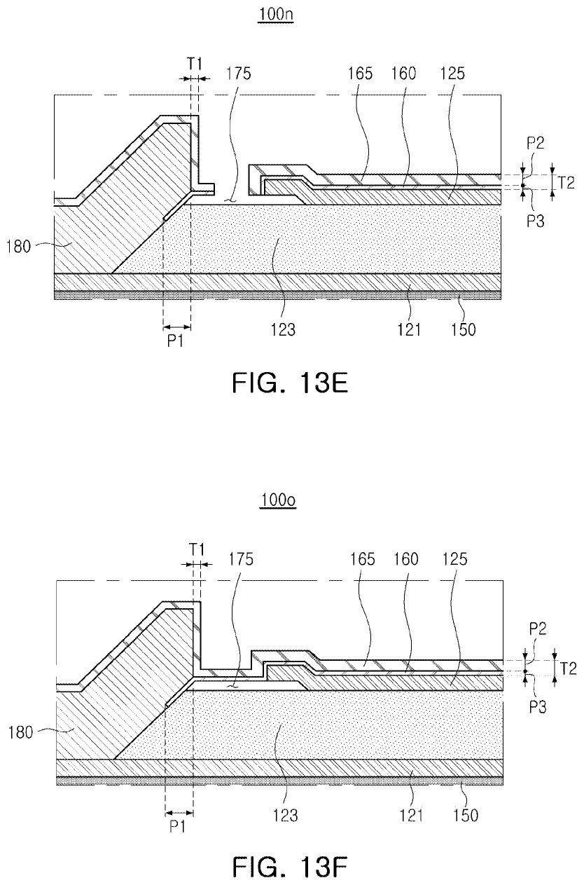

FIGS. 13A through 13F are cross-sectional views illustrating a modified structure of a resonant unit of a bulk acoustic resonator according to an example embodiment in the present disclosure.

Referring to FIGS. 13A and 13B, bulk acoustic resonators 100i and 100j according to an example embodiment in the present disclosure may not include an insertion layer, and the piezoelectric layer 123 of the bulk acoustic resonators 100i and 100j may not be raised. Depending on the design, a lateral acoustic wave suppression structure may be replaced with a structure in which the thickness P5 of the edge portion of the second electrode 125 is different from the thickness P4 of the other portions.

Referring to FIG. 13C, the second electrode 125 of a bulk acoustic resonator 100k according to an example embodiment may be disposed on the entire upper surface of the piezoelectric layer 123 in the resonant unit. Accordingly, at least a portion of the second electrode 125 may also be formed on the extended portion 1232, as well as on the inclined portion 1231 of the piezoelectric layer 123.

Referring to FIG. 13D, a bulk acoustic resonator 100m according to an example embodiment in the present disclosure may further include an edge cavity 175, and the edge cavity 175 may raise the second electrode 125 at an edge surrounding the center of the resonant unit. Accordingly, the edge cavity 175 may be formed between the edge of the second electrode 125 and the piezoelectric layer 123. For example, the edge cavity 175 may be formed of air.

For example, a structure similar to the insertion layer may be formed in a space occupied by the edge cavity 175 after the piezoelectric layer 123 is formed and before the second electrode 125 and the first metal layer 180 are formed. Thereafter, the second electrode 125, the protective layer 160, the first metal layer 180, and the frequency control layer 165 may be formed. Thereafter, a portion in which the second electrode 125, the protective layer 160, and the frequency control layer 165 are disposed on the upper side of the structure similar to the insertion layer may be etched, and the structure similar to the insertion layer may be removed in a manner similar to the method of forming the cavity in the present disclosure.

Referring to FIG. 13E, a portion of the second electrode 125 of a bulk acoustic resonator 100n according to an example embodiment in the present disclosure may not be removed when the portion removed on the upper side of the edge cavity 175 is removed. Accordingly, a portion of each of the protective layer 160 and the frequency control layer 165 may be disposed to cover the side surface of the second electrode 125 in a portion removed on the upper side of the edge cavity 175.

Referring to FIG. 13F, a bulk acoustic resonator 100o according to an example embodiment in the present disclosure may have a structure in which an upper surface of the edge cavity 175 is not exposed upwardly. For example, a passage for forming the edge cavity 175 may be formed in a horizontal direction rather than on the upper side of the edge cavity 175.

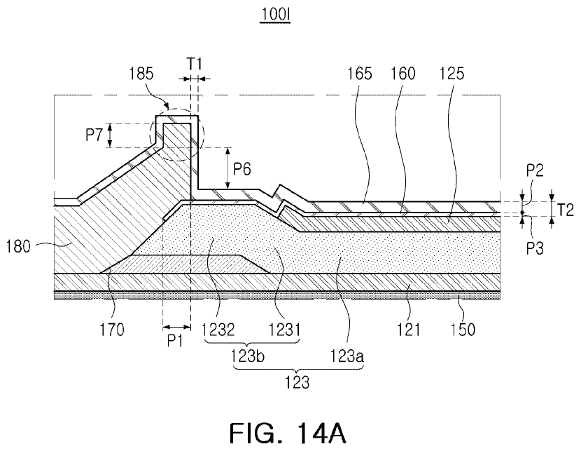

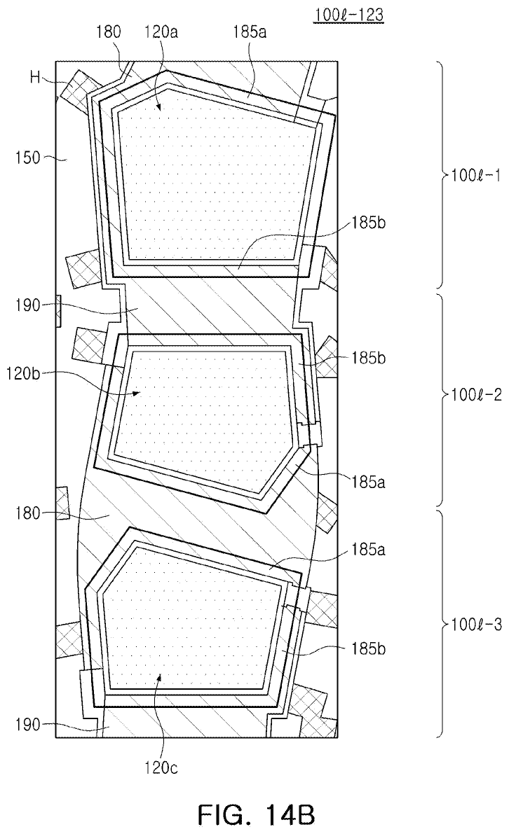

FIGS. 14A and 14B are cross-sectional views illustrating a modified structure of a metal layer of a bulk acoustic resonator according to an example embodiment in the present disclosure.

Referring to FIG. 14A, a portion adjacent to the second electrode 125 in the first metal layer 180 of a bulk acoustic resonator 100l according to an example embodiment in the present disclosure has a protrusion 185 protruding upwardly by a length P7.

Accordingly, connection resistance between the first electrode 121 and the first metal layer 180 or connection resistance between the second electrode 125 and the second metal layer may be lowered, so that input/output loss of the bulk acoustic resonator 100l may be further reduced.

In addition, a length (P6+P7) over which the frequency control layer 165 covers the side surface of the first metal layer 180 may be longer, and the frequency control layer 165 may have improved trim uniformity without being substantially affected by the length (P6+P7).

Referring to FIG. 14B, a plurality of bulk acoustic resonators 100l-1, 100l-2, and 100l-3 according to an example embodiment in the present disclosure may include a plurality of resonant units 120a, 120b, and 120c, respectively, and may be connected to each other through the first metal layer 180 or the second metal layer 190.

The first metal layer 180 may include a protrusion 185a surrounding some of the plurality of resonant units 120a, 120b, and 120c, and the second metal layer 190 may include a protrusion 185b surrounding the remainder of the plurality of resonant units 120a, 120b, and 120c. The protrusion 185 of FIG. 14A may be the protrusion 185a or the protrusion 185b of FIG. 14B.

The filter 100l-123 may have a structure in which a plurality of bulk acoustic resonators 100l-1, 100l-2, and 100l-3 are connected to each other.

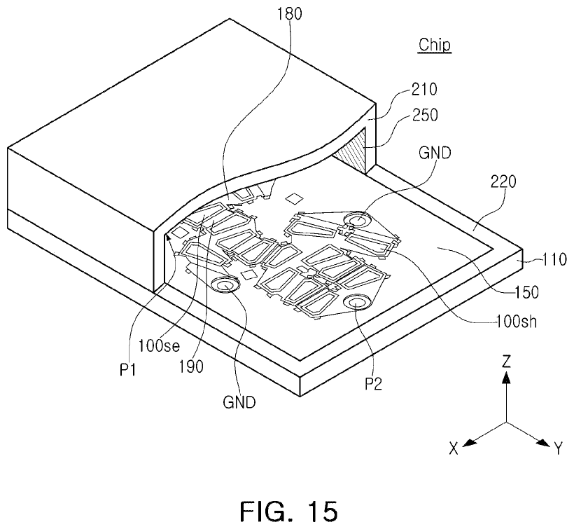

FIG. 15 is a perspective view illustrating a filter including a bulk acoustic resonator according to an example embodiment in the present disclosure.

Referring to FIG. 15, bulk acoustic resonators 100se and 100sh according to an example embodiment in the present disclosure may be at least one series bulk acoustic resonator 100se and/or at least one shunt bulk acoustic resonator 100sh.

The at least one series bulk acoustic resonator 100se may be electrically connected between a first port P1 and a second port P2, and the at least one shunt bulk acoustic resonator 100sh may be electrically connected between the at least one series bulk acoustic resonator 100se and a ground port GND.

Depending on a relationship of the resonant frequency and/or antiresonant frequency between the at least one series bulk acoustic resonator 100se and the at least one shunt bulk acoustic resonator 100sh, the filter (chip) may be implemented as a bandpass filter or a notch filter.

Since the bulk acoustic resonators 100se and 100sh according to an example embodiment in the present disclosure may reduce the lateral wave itself or leakage of the lateral wave to the side, energy loss when the RF signal passes through each of the bulk acoustic resonators 100se and 100sh may be reduced, and thus, the overall insertion loss and/or return loss of the filter (chip) may be reduced. In addition, since spurious near the resonant frequency according to the lateral wave may be reduced, the attenuation characteristic at the end of the bandwidth of the filter (chip) may also be sharper.

Each of the first port P1, the second port P2, and the ground port GND may have a vertical electrical path passing through the substrate 110, and may be electrically connected to a printed circuit board (PCB) that may be disposed on a lower surface of the filter (chip).

The bulk acoustic resonators 100se and 100sh according to an example embodiment in the present disclosure may be accommodated in a cap 210 between the substrate 110 and the cap 210, and a bonding member 220 may bond the cap 210 to the substrate 110 and/or the membrane layer 150. For example, the bonding member 220 may include a eutectic bonding structure including a conductive ring or an anodic bonding structure.

Depending on the design, a shield layer 250 may be disposed on all or most of the lower surface and/or the inner surface of the cap 210, and may be connected to the bonding member 220.

The bulk acoustic resonator according to an example embodiment in the present disclosure may have improved performance (e.g., notch reduction) according to improved trim uniformity and may be stably implemented according to improved galvanic isolation. A filter including the bulk acoustic resonator may reduce energy loss or reduce heat generation according to the improved performance of the bulk acoustic resonator.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic resonator comprising:
a substrate;
a frequency control layer changing a resonant frequency or antiresonant frequency of the bulk acoustic resonator according to a thickness of the frequency control layer;
a piezoelectric layer disposed between the frequency control layer and the substrate;
a first electrode disposed between the piezoelectric layer and the substrate;
a second electrode disposed between the piezoelectric layer and the frequency control layer;
a metal layer connected to the first electrode or the second electrode; and
a protective layer disposed between the second electrode and the frequency control layer,
wherein the frequency control layer covers a larger area than that of the protective layer.

2. The bulk acoustic resonator of claim 1, wherein the frequency control layer covers at least a portion of a surface of the protective layer facing the frequency control layer and a surface of the metal layer facing the frequency control layer.

3. The bulk acoustic resonator of claim 2, wherein at least a portion of the metal layer is disposed between a portion of the frequency control layer and a portion of the protective layer.

4. The bulk acoustic resonator of claim 2, wherein
the frequency control layer further covers a side surface of the metal layer, and
a thickness of a portion of the frequency control layer covering the side surface of the metal layer is thinner than a thickness of a portion of the frequency control layer covering the second electrode.

5. The bulk acoustic resonator of claim 1, wherein a thickness of the protective layer is 30 nm or more, and is thinner than a thickness of a portion of the frequency control layer covering the protective layer.

6. The bulk acoustic resonator of claim 5, wherein the thickness of the portion of the frequency control layer covering the protective layer is 60 nm or more.

7. The bulk acoustic resonator of claim 1, wherein a thickness of a portion of the frequency control layer covering the protective layer is 60 nm or more and is thinner than a thickness of the protective layer.

8. The bulk acoustic resonator of claim 1, wherein a frequency sensitivity, which is a rate of change of the resonant frequency or antiresonant frequency of the bulk acoustic resonator according to a change in a thickness of the frequency control layer, is different from a frequency sensitivity of the protective layer.

9. The bulk acoustic resonator of claim 1, wherein each of the protective layer and the frequency control layer includes one or more of SiO₂, Si₃N₄, Al₂O₃ and AlN, or includes the same material as a piezoelectric material included in the piezoelectric layer.

10. The bulk acoustic resonator of claim 9, wherein one of the protective layer and the frequency control layer includes SiO₂, the other of the protective layer and the frequency control layer includes one or more of Si₃N₄, Al₂O₃ and AlN, or includes the same material as the piezoelectric material included in the piezoelectric layer.

11. The bulk acoustic resonator of claim 10, wherein a thickness of the layer including SiO₂ among the protective layer and the frequency control layer is greater.

12. The bulk acoustic resonator of claim 1, wherein the protective layer has stronger chemical resistance than that of the frequency control layer.

13. The bulk acoustic resonator of claim 1, wherein the metal layer is thicker than each of the first and second electrodes, and the metal layer includes a material different from a material included in each of the first and second electrodes.

14. The bulk acoustic resonator of claim 1, further comprising:
an insertion layer partially disposed between the first and second electrodes,
wherein one or more of the protective layer and the frequency control layer includes a portion raised by the insertion layer.

15. A filter comprising:
a plurality of bulk acoustic resonators,
wherein two or more of the plurality of bulk acoustic resonators comprise the bulk acoustic resonator of claim 1, and
wherein thicknesses of the frequency control layers of at least two of the two or more of the plurality of bulk acoustic resonators are different from each other.

16. A bulk acoustic resonator comprising:
a substrate;
a frequency control layer covering toward the substrate and changing a resonant frequency or antiresonant frequency of the bulk acoustic resonator according to a thickness of the frequency control layer;
a metal layer having at least a portion covered by the frequency control layer and connected to a first electrode or a second electrode;
a resonant unit including the second electrode, the first electrode disposed between the second electrode and the substrate, and a piezoelectric layer disposed between the first and second electrodes; and
a protective layer having at least a portion disposed between the metal layer and the second electrode and between the substrate and the frequency control layer.

17. The bulk acoustic resonator of claim 16, wherein at least a portion of the metal layer is disposed between at least a portion of the frequency control layer and at least a portion of the protective layer.

18. The bulk acoustic resonator of claim 16, wherein
the frequency control layer covers a side surface of the metal layer, and
a thickness of a portion of the frequency control layer covering the side surface of the metal layer is thinner than a thickness of a portion of the frequency control layer covering the protective layer.

19. The bulk acoustic resonator of claim 16, wherein
a thickness of the protective layer is 30 nm or more, and is thinner than a thickness of the portion of the frequency control layer covering the protective layer, and
a thickness of the portion of the frequency control layer covering the protective layer is 60 nm or more.

20. The bulk acoustic resonator of claim 16, wherein each of the protective layer and the frequency control layer includes one or more of SiO₂, Si₃N₄, Al₂O₃ and AlN, or includes the same material as a piezoelectric material included in the piezoelectric layer.

21. The bulk acoustic resonator of claim 20, wherein the protective layer and the frequency control layer include different materials.

22. The bulk acoustic resonator of claim 16, wherein
the metal layer is thicker than each of the first and second electrodes, and
the metal layer includes a material different from a material included in each of the first and second electrodes.

23. The bulk acoustic resonator of claim 16, further comprising an insertion layer partially disposed in the resonant unit,
wherein one or more of the protective layer and the frequency control layer includes a portion raised by the insertion layer.

24. A bulk acoustic resonator comprising:
a substrate;
a frequency control layer changing a resonant frequency or antiresonant frequency of the bulk acoustic resonator according to a thickness of the frequency control layer;
a piezoelectric layer disposed between the frequency control layer and the substrate;
a first electrode disposed between the piezoelectric layer and the substrate;
a second electrode disposed between the piezoelectric layer and the frequency control layer;
a metal layer connected to the first electrode or the second electrode; and
a protective layer disposed between the second electrode and the frequency control layer,
wherein one of the frequency control layer and the protective layer has a positive temperature coefficient of frequency (TCF) and the other thereof has a negative TCF.

25. The bulk acoustic resonator of claim 24, wherein
one of the protective layer and the frequency control layer includes SiO₂, and
the other of the protective layer and the frequency control layer includes one or more of Si₃N₄, Al₂O₃ and AlN or includes the same material as the piezoelectric material included in the piezoelectric layer.

26. The bulk acoustic resonator of claim 24, wherein the frequency control layer covers at least a portion of a surface of the protective layer facing the frequency control layer and a surface of the metal layer facing the frequency control layer.

27. The bulk acoustic resonator of claim 26, wherein at least a portion of the protective layer is between the metal layer and the second electrode and between the substrate and the frequency control layer.

28. A bulk acoustic resonator comprising:
a substrate, a first electrode, a piezoelectric layer, and a second electrode stacked;
a metal layer connected to the first electrode;
a protective layer disposed between the second electrode and the metal layer to increase galvanic corrosion resistance; and
a frequency control layer disposed on the protective layer and comprising a predetermined thickness to control a resonant frequency or antiresonant frequency of the bulk acoustic resonator.

29. The bulk acoustic resonator of claim 28, wherein the frequency control layer is disposed on the metal layer.

30. The bulk acoustic resonator of claim 28, wherein a portion of the metal layer is disposed between the frequency control layer and the protective layer.

31. A filter comprising:
two or more bulk acoustic resonators each comprising the bulk acoustic resonator of claim 28,
wherein the predetermined thicknesses of the frequency control layers of at least two of the two or more bulk acoustic resonators are different from each other.

32. The filter of claim 31, wherein at least one of the at least two of the two or more bulk acoustic resonators is a series bulk acoustic resonator.

33. The filter of claim 32, wherein at least one of the at least two of the two or more bulk acoustic resonators is a shunt bulk acoustic resonator connected between the series bulk acoustic resonator and a ground.
